(19) United States
(12) Patent Application Publication
(10) Pub. No.: US 2008/0073061 A1
(43) Pub. Date: Mar. 27, 2008

(54) Variable depth microchannels

(76) Inventors: Rajen Dias, Phoenix, AZ (US); Lars Skoglund, Chandler, AZ (US)

Correspondence Address: INTEL CORPORATION;c/o INTELLEVATE, LLC, P.O. BOX 52050, MINNEAPOLIS, MN, 55402, US

(21) Appl. No.: 11/528,773

(22) Filed: Sep. 27, 2006

(51) Int. Cl. H05K 7/20

(52) U.S. Cl. 165/80.4; 165/146; 165/104.33; 361/700

(57) ABSTRACT

A channel heat exchanger and cooling system with plan-wise variable rate of cooling that corresponds, in part, to a plan-wise variable heat flux and a method of manufacturing and using same.

### TECHNICAL FIELD

The invention relates to the field of microelectronics. More particularly, but not exclusively, the invention relates to cooling of microelectronics using micro-channel heat exchangers and a process for manufacturing same.

### BACKGROUND

Under normal operation, integrated circuits such as processors generate heat which must be removed to maintain the device temperature below a critical threshold value to maintain reliable device operation. The threshold temperature results from any number of short or long term reliability failure modes and is specified by the circuit designer as part of a normal integrated circuit design cycle. The evolution of integrated circuit designs results in higher operating frequency, increased numbers of transistors, and physically smaller devices. To date this trend has resulted in both increasing power and increasing heat flux devices. This trend has also resulted in non-uniform heat flux among device circuitry and therefore non-uniform die temperature, or hotspots. For example, single core and mutli-core processors may have highly non-uniform and concentrated heat flux. Alternatively, a graphics processor, a memory controller, an ASIC, a chipset, or other integrated circuit may also exhibit non-uniform and concentrated heat flux. FIG. 1 illustrates a simplified representation of a single core processor 100, wherein a region of low power circuitry 102 surrounds a core region of high power circuitry 104. In such processors, a core area with high heat flux 104 may account for less than half of the total die area but dissipate a majority of the die power. The remaining die area 102 may be reserved for cache or other low power functions which generate significantly less heat. These trends are expected to continue.

Often, circuitry near a hot spot dissipates higher power than circuitry elsewhere on a die, while increased performance and reliability may be achieved if the high power circuitry operates at similar or lower temperature than at other regions. Consequently, die hot spots often need increased cooling. To effectuate increased cooling, liquid phase or liquid to gas phase cooling may be used in conjunction with a heat exchanger to transfer heat from a die with an integrated circuit disposed thereon to a coolant. The trend to higher power, higher average heat flux, and higher levels of non-uniform heat flux in microelectronic devices demands continual improvement in cooling technology to prevent occurrence of thermally induced failures.

The terms “fins” and “micro-fins” will be used interchangeably throughout, as will the terms “channel” and “micro-channel”.

A fluid-filled microchannel heat exchanger offers one technique for cooling an integrated circuit die. A micro-channel heat exchanger cools a heat source by conducting heat from the device to the walls and micro-fins that form the heat exchanger's micro-channels. The working fluid, or coolant, removes the heat from the walls and micro-fins through convective heat transfer as it passes through the channels between the walls and fins. Heat, once removed from the device and stored in the fluid, is removed from the heat exchanger simply by removing the fluid. Convective heat transfer to the fluid may be enhanced by surface treatments, for example by controlling surface roughness. Depending on desired cooling performance, some embodiments of micro-channel heat exchangers attach to a die or an integrated circuit package while other embodiments of a micro-channel heat exchanger may be formed integrally to the bulk silicon that forms a die substrate.

Microchannels presently may be formed by a chemical etching processes, for example, a Deep Reactive Ion Etching (DRIE) process. However, DRIE limits attainable surface roughness ranges and provides an approximately uniform channel depth. See FIG. 2 for an example of an embodiment of an approximately uniform channel depth microchannel heat exchanger 200. The microchannel heat exchanger 200 includes a plurality of fins 206 with a region to be exposed to a working fluid 208. The fins 206 protrude from a base 214 where a side opposite that from which the fins protrude 202 forms a substantially planar surface. Sealingly engaging a lid (not shown) to a distal end 204 of two or more adjacent fins 206 forms a channel to receive a coolant. Because the rate of etching cannot generally be controlled channel by channel, each channel has approximately the same depth 210. Section A-A illustrates a cross-section view of a representative uniform depth channel with a heat exchanger base 214 of substantially plan-wise constant thickness exposed to a plan-wise variable heat flux 212 that may result from a die with non-uniform heat flux similar to that illustrated by FIG. 1.

Typically, a microchannel heat exchanger forms part of a closed loop cooling system that uses a pump to circulate a fluid between a microchannel heat exchanger, where the fluid absorbs heat from a processor or other integrated circuit die as described above, and a remote heat exchanger which rejects the heat, generally to the environment. Heat transfer between the microchannel walls and the fluid may be greatly improved if sufficient heat is conducted into the fluid to cause vaporization. The latent heat of vaporization measures the energy required to change a unit of fluid from the liquid state to the gaseous (vapor) state. Such “two-phase” heat transfer absorbs significantly more energy than single phase heat transfer because the fluid's latent heat of vaporization is generally quite large compared to the fluid's specific heat, which measures the energy in a unit of fluid at a given temperature. For example, heating 50 grams of liquid water, at atmospheric pressure, from 0° C. to 100° C. requires 21 kJ of heat while vaporizing the same quantity of water at 100° C. and atmospheric pressure requires 113 kJ. A typical system expels the latent heat when fluid vapor condenses to liquid, often in a remote heat exchanger. While water is a particularly useful fluid to use in two-phase systems because it is inexpensive, has a high latent heat (or enthalpy) of vaporization and boils at a temperature (again at atmospheric pressure) well suited to cooling integrated circuits, other examples of coolants, such as alcohols, perflourinated liquids, etc. may also be well suited for cooling electronics.

While convective heat transfer afforded by fluid-filled microchannel heat exchangers offers significant advantages, conduction heat transfer still plays a significant role in limiting system cooling capacity. For example, in a typical system, heat conducts from active circuitry on a die, through the die substrate, often across a thermal interface material into a heat exchanger, and through the heat exchanger walls and fins before reaching the working fluid of the heat exchanger.

### BRIEF DESCRIPTION OF THE DRAWINGS

FIG. 1 illustrates an embodiment of a plan-wise variable heat flux at a surface of an integrated circuit die.

FIG. 2 illustrates a cross-section view parallel to a plurality of channels and a cross-section view perpendicular to the plurality of channels in a prior art microchannel heat exchanger with approximately uniform channel depth.

FIG. 3 illustrates a plan view of an embodiment of a variable depth microchannel heat exchanger.

FIG. 4 illustrates a cross-section view parallel to a plurality of channels and a cross-section view perpendicular to the plurality of channels in an embodiment of a variable channel depth microchannel heat exchanger.

FIG. 5 illustrates a cross-section view parallel to a plurality of channels in an embodiment of a variable depth microchannel heat exchanger.

FIG. 6 illustrates the embodiment of FIG. 5 thermally coupled to an integrated circuit (IC) package using a thermal interface material and mechanical retention mechanism.

FIG. 7 illustrates the embodiment of FIG. 5 thermally coupled to an IC package using a solder and a solderable material.

FIG. 8 illustrates the embodiment of FIG. 5 thermally coupled to an IC package using a thermal adhesive.

FIG. 9 illustrates an embodiment of an integrated circuit cooling system that incorporates a variable depth microchannel heat exchanger.

FIG. 10 illustrates an embodiment of a method of manufacture for a variable depth microchannel heat exchanger.

FIG. 11 illustrates an embodiment of a method of use for a variable depth microchannel heat exchanger.

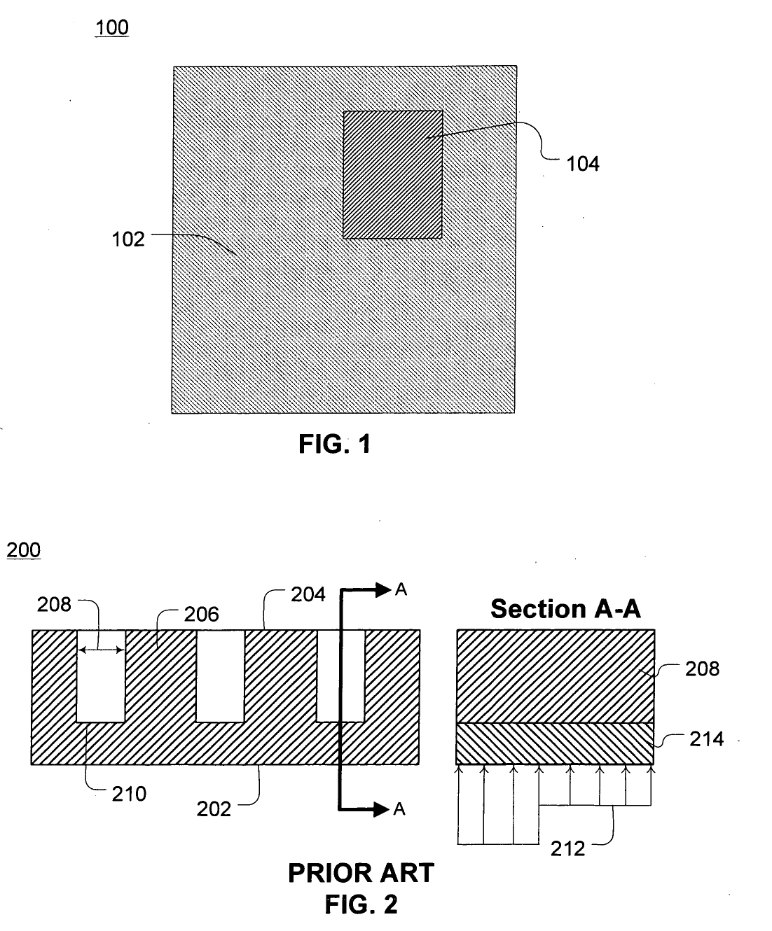

### DETAILED DESCRIPTION

Herein disclosed are a method, apparatus, and system for providing a desired distribution of heat transfer rate using a microchannel heat exchanger and a method of manufacturing same.

In the following detailed description, reference is made to the accompanying drawings which form a part hereof, wherein like numerals designate like parts throughout and in which are shown, by way of illustration, specific embodiments in which the invention may be practiced. Other embodiments may be utilized and structural or logical changes may be made without departing from the intended scope of the embodiments presented. It should also be noted that directions and references (e.g., up, down, top, bottom, primary side, backside, etc.) may be used to facilitate the discussion of the drawings and are not intended to restrict the application of the embodiments of this invention. Therefore, the following detailed description is not to be taken in a limiting sense and the scope of the embodiments of the present invention is defined by the appended claims and their equivalents.

### Microchannel Fin and Base Structure

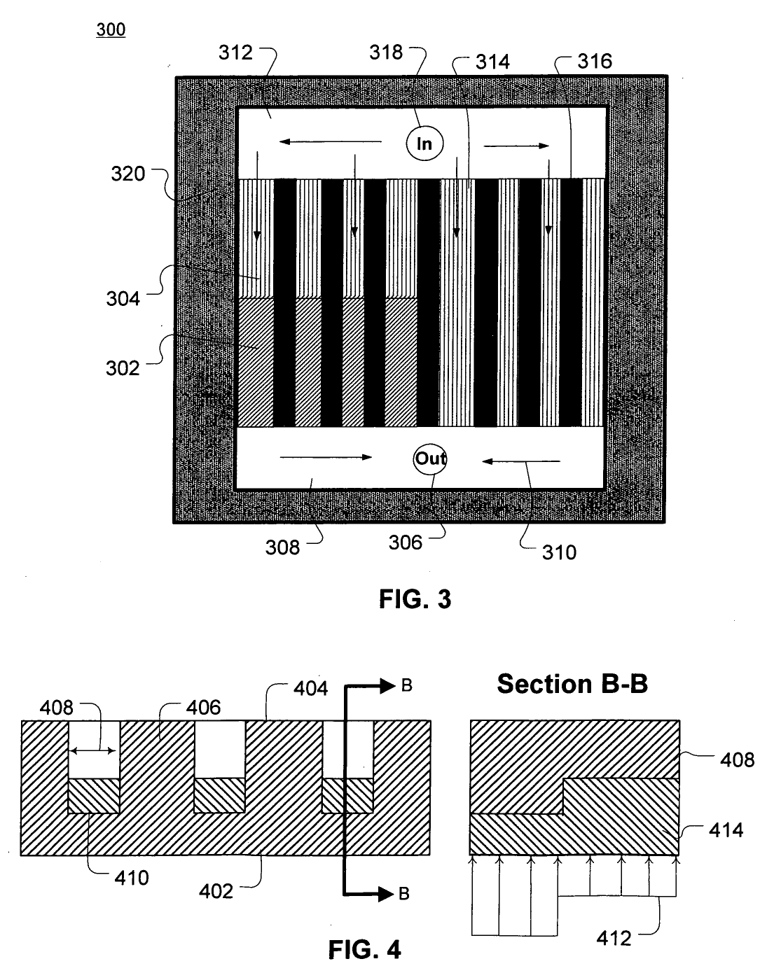

FIG. 3 illustrates a plan view of an embodiment of a plan-wise variable depth microchannel heat exchanger 300. The illustrated heat exchanger 300 core includes a base of plan-wise variable thickness. In some embodiments, the plan-wise variable distribution of base thickness may correspond to an incident heat flux, for example a heat flux that emanates from a single core processor. For simplicity of illustration, in the embodiment of FIG. 3 the base forms two regions 302 and 304, illustrated by different hashing, each with a different thickness. In other embodiments, the base thickness may vary continuously or have a plurality of distinct thickness. Returning to FIG. 3, the core of heat exchanger 300 also includes a plurality of fins 316 that form a plurality of channels 314 through which a coolant may pass. A wall 320 surrounds the heat exchanger core and forms an inlet plenum 312 and an outlet plenum 308, with an inlet 318 and outlet 306, respectively. The inlet plenum 312 and outlet plenum 308 hydraulically couple the micro-channels 314. Arrows 310 illustrate an exemplary coolant flow path. Although the plenums illustrated hydraulically couple the micro-channels 314 substantially in parallel, other embodiments will be apparent to those skilled in the art in which micro-channels may be hydraulically coupled in series, or in which a first plurality of micro-channels is hydraulically coupled in series and a second plurality of micro-channels is hydraulically coupled in parallel.

FIG. 4 illustrates a cross-section view parallel to a plurality of channels and a cross-section view perpendicular to the plurality of channels in an embodiment of a variable channel depth microchannel heat exchanger similar to that illustrated in FIG. 3. The embodiment of FIG. 4 includes a base 414 with plan-wise variable thickness, illustrated by Section B-B. The plurality of fins 406 with a surface to be exposed to a coolant 408 form a first region of first depth protruding from one side of, and integral to, the base 414 and a second region of second depth also extending from the one side of and integral to the base 414. The side of the base opposite that from which the fins protrude 402 forms a substantially planar surface. The difference in fin 408 depth between the first region and the second region results in the plan-wise variable thickness of the base 414 and forms a channel of variable depth 410. Although the embodiment shown in FIG. 4 forms a single channel of various depth, other embodiments exist where a first channel has uniform depth, while a different channel channel has uniform depth different than the first channel. Alternatively, an embodiment may form a first plurality of channels of first depth and a second plurality of channels of variable depth. Returning to FIG. 4, a lid (not shown) sealingly engaged to an end 404 of two or more fins distal from the base will form a plurality of micro-channels, as illustrated by FIG. 3 at 314, defining a volume to receive a coolant. In some embodiments, the coolant may consist substantially of water, propylene glycol, perflourinated fluid, an inorganic liquid, or a combination thereof.

The depth 410 of the micro-channels may correspond to an plan-wise variable incident heat flux 412, where the longer arrows of the illustrated flux 412 correspond to a first flux and the shorter arrows of the illustrated flux 412 correspond to a second flux. In some embodiments where the plan-wise variable depth 410 corresponds to a plan-wise variable heat flux 412, a deeper channel may correspond to a higher heat flux, as illustrated in Section B-B.

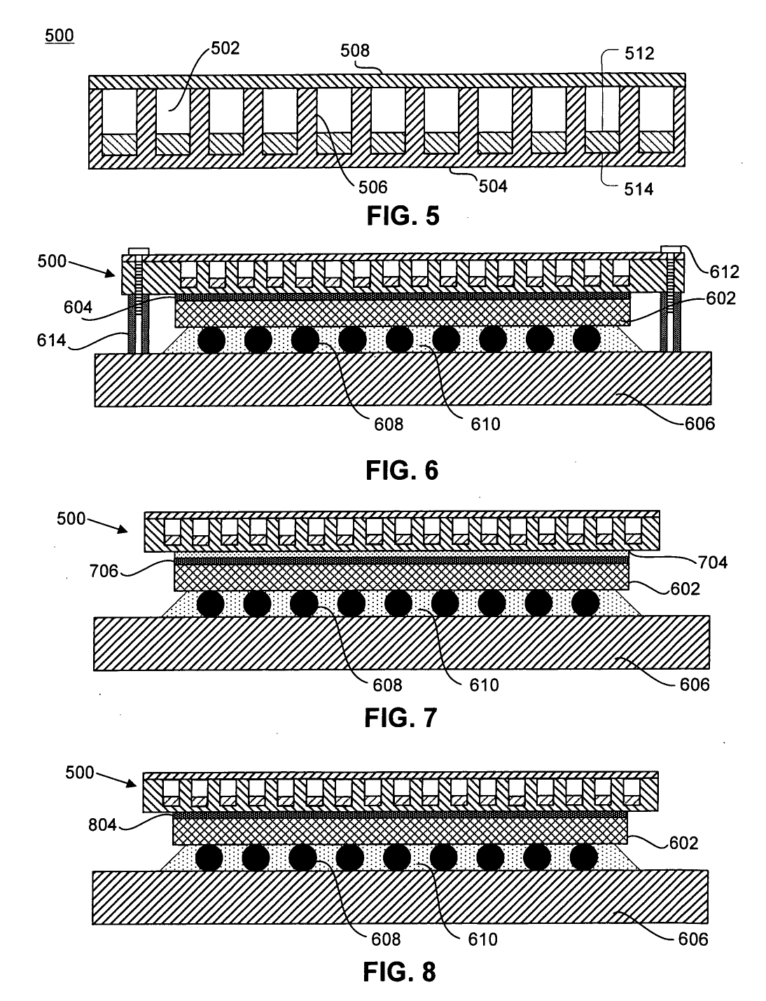

FIG. 5 illustrates a variable depth micro-channel heat exchanger 500 similar to those illustrated in FIG. 3 and FIG. 4 that includes a plurality of fins 506 formed integrally to the base 504. The lid 508 sealingly engages the fins 506. The fins 506 and lid 508 form a plurality of micro-channels 502, each with a first depth 512 and a second depth 514. In one embodiment (not illustrated), the substrate from which the fins 506 and base 504 are formed forms a die substrate on which is disposed an integrated circuit. For example, the fins 506 and base 504 may be formed integrally to the bulk silicon substrate of a silicon die.

Alternatively, the fins 506 and base 504 may be formed from a substrate distinct from a die, wherein the micro-channel heat exchanger to be thermally coupled to an integrated circuit die, similar to the embodiments illustrated by FIG. 6 through FIG. 8. FIG. 6 illustrates the embodiment of FIG. 5 thermally coupled to an integrated circuit (IC) package using a thermal interface material 604 and mechanical retention mechanism. In the embodiment of FIG. 6, the mechanical retention mechanism includes an externally threaded member 612, such as a screw or bolt, that extends through a portion of the heat exchanger structure and threads into an internally threaded member 614, such as a threaded bushing (as illustrated) or a nut (not shown). The thermal interface material 604 is disposed between the heat exchanger 500 and the top of the IC package 602, for example a die backside in a case of a bare die package, a die encapsulant, for example in a Ball Grid Array (BGA) package, or an integrated heat spreader disposed over a die to spread heat dissipated by a die. The thermal interface material 604 may serve several purposes; first, it may provide a conductive heat transfer path from the package 602 to heat exchanger 500 and, second, because the thermal interface material 604 may be compliant and may adhere well to both the package top 602 and heat exchanger 500, the thermal interface material may act as a flexible buffer to accommodate physical stress resulting from differences in the coefficients of thermal expansion (CTE) between the package 602 and heat exchanger 500. The electrical interconnect 608 of the IC package may include solder balls, lead frames, lands (as in a Land Grid Array (LGA) package). Underfill 610 disposed between a substrate 606, such as a printed circuit board or package substrate, may strengthen the package. Although FIG. 6 illustrates use of threaded fasteners to retain the heat exchanger 500, other means of mechanical retention may be employed including retention clips that extend over the heat exchanger 500 that press the heat exchanger 500 toward the package top 602, thereby exerting pressure on the thermal interface material 604 disposed between the heat exchanger 500 and package top 602.

Alternatively, FIG. 7 illustrates the embodiment of FIG. 5 thermally coupled to an IC package similar to that illustrated by FIG. 6, using a solder 706 and a solderable material 704. Soldering heat exchanger 500 to the package 602 may eliminate the need for the threaded fasteners 612 and 614 of FIG. 4. Solderable material 706 may comprise any material to which the selected solder will bond. Such materials include but are not limited to metals such as copper (Cu), gold (Au), nickel (Ni), aluminum (Al), titanium (Ti), tantalum (Ta), silver (Ag) and Platinum (Pt). In one embodiment, the layer of solderable material may comprise a base metal over which another metal may be formed as a top layer. In another embodiment, the solderable material may comprise a noble metal; such materials resist oxidation at solder reflow temperatures, thereby improving the quality of the soldered joints. In another embodiment, both heat exchanger 500 and solderable material 706 may be copper.

The layer (or layers) of solderable material may be formed over the top surface of the package 602 using one of many well-known techniques common to industry practices. For example, such techniques may include but are not limited to sputtering, vapor deposition (chemical and physical), and plating. The formation of the solderable material layer may occur prior to die fabrication (i.e., at the wafer level) or after die fabrication processes are performed.

In one embodiment solder 704 may initially comprise a solder preform having a pre-formed shape conducive to the particular configuration of the bonding surfaces. The solder preform is placed between the die and the metallic heat exchanger during a pre-assembly operation and then heated to a reflow temperature at which point the solder melts. The temperature of the solder and joined components are then lowered until the solder solidifies, thus forming a bond between the joined components.

FIG. 8 illustrates the embodiment of FIG. 5 thermally coupled to an IC package similar to that illustrated by FIG. 6 using a thermal adhesive 804, such as a thermally conductive, double sided adhesive tape or a thermally conductive epoxy. Thermal adhesives, sometimes called thermal epoxies, are a class of adhesives that may provide good to excellent conductive heat transfer rates. A thermal adhesive may employ fine portions (e.g., granules, slivers, flakes, micronized, etc.) of a metal or ceramic, such as silver or alumina, distributed within in a carrier (the adhesive), such as epoxy.

The heat exchanger 500 need not comprise a metal. The heat exchanger 500 may be made of any material that provides good conductive heat transfer properties. For example, a ceramic carrier material embedded with metallic pieces in a manner to the thermal adhesives discussed above may be employed for the heat exchanger. Additionally, a heat exchanger of similar properties may be employed in the embodiments of FIG. 6 through FIG. 8 if, in the case of the embodiment of FIG. 7, a layer of solderable material is formed over surface areas that are soldered to the IC package (e.g., the base of micro-channel heat exchanger 500).

### Embodiments Utilizing Two Phase Coolant Flow and Refrigeration Cycles

Some embodiments may utilize two phase coolant flows or refrigeration cycles. Other embodiments may reverse the coolant flow direction from that shown in the figures to effectuate more efficient cooling through applying a cool incoming flow to a high heat flux region, thus increasing cooling efficiency of the heat exchanger.

### Variable Depth Micro-channel Cooling System

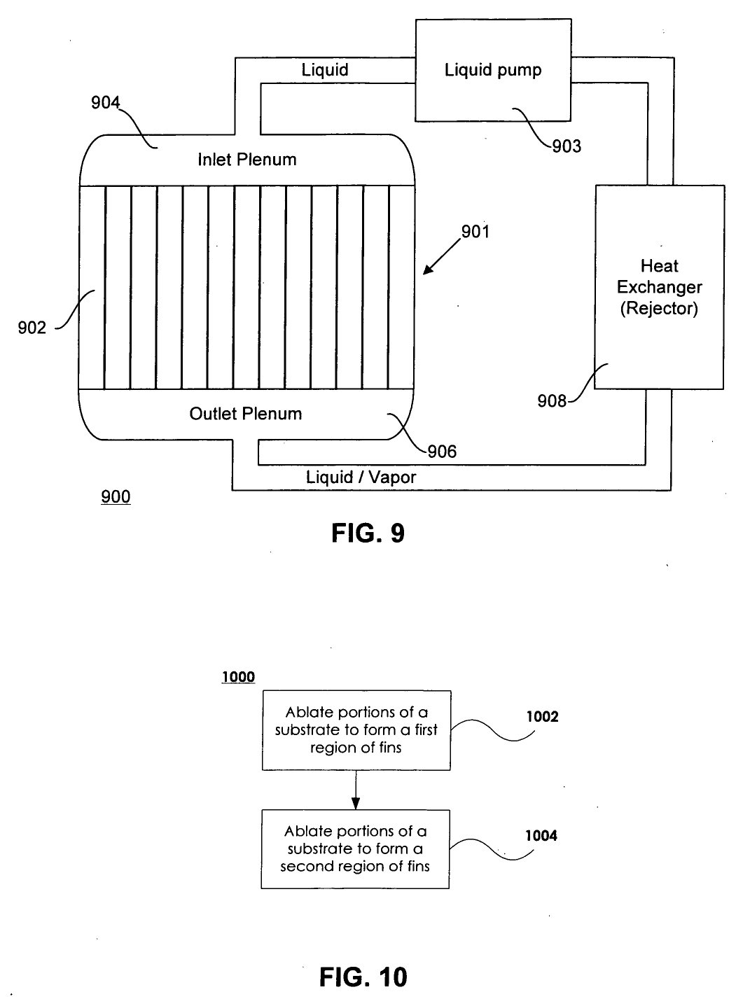

FIG. 9 illustrates one embodiment of a closed loop cooling system 900 with a heat exchanger 901 with variable depth micro-channels 902 coupled thermally to an IC die or package (not shown). System 900 includes a microchannel heat exchanger 901 with inlet plenum 904 and outlet plenum 906. As in FIG. 3, the plenums illustrated may hydraulically couple a plurality of micro-channels in series or parallel. The system 900 further includes a remote heat exchanger 908, and a pump 903. Although the system 900 as described uses a single phase cooling cycle, system 900 may take advantage of the fact that a fluid undergoing a phase transition from a liquid state to a vapor state absorbs a significant amount of energy, known as latent heat, or heat of vaporization. This absorbed heat being stored in the fluid, in a vapor state or saturated mixture of vapor and liquid, can be subsequently removed from the fluid by condensing the coolant from vapor state to liquid state. The variable depth micro-channels 902, which typically have hydraulic diameters on the order of one hundred-micrometers, are effective for facilitating the phase transition from liquid to vapor. Consequently, a two phase cooling loop, where phase transition from liquid to vapor occurs in the variable depth micro-channel heat exchanger 901, may cool the processor. In another embodiment, a variable depth micro-channel heat exchanger 901 may act as an evaporator in a refrigeration cycle, and the remote heat exchanger 908 may act as a condenser in the refrigeration cycle.

System 900 may function as follows. The heat from the IC (not shown in FIG. 9) may conduct into the microchannel heat exchanger 901, thereby increasing the temperature of the walls of the microchannels. Liquid may be forced by pump 903 into an inlet plenum 904, where the liquid may enter the inlet of the microchannels. As the liquid passes through the microchannels, convective heat transfer may occur between the microchannel walls and the liquid. For embodiments without phase change, so called single phase flows, a majority liquid phase may exit the micro-channels at the outlet plenum 906 and the remote heat rejecter 908 may remove heat from the coolant without the coolant undergong phase transition. In a two phase heat exchanger, a portion of the fluid may exit the microchannels as a vapor at outlet plenum 906. The heated liquid or vapor then enters a second heat exchanger 908 to reject a portion of the heat absorbed by the variable depth micro-channel heat exchanger 901. The heat rejecter may include a second heat exchanger that condenses the vapor phase to a liquid phase. The pump 903 then receives the liquid coolant at an inlet side, thus completing the cooling cycle.

### Method of Manufacture for Non-uniform Depth Microchannels

FIG. 10 illustrates a flow chart of a method 1000 of manufacturing a variable depth micro-channel heat exchanger using a laser milling process. In block 1002, part of a substrate is ablated to form a first region of fins. In block 1004, part of the substrate is ablated to form a second region of fins. A depth of the first region and a depth of the second region differ.

A laser milling process may be used to ablate the substrate in the above described process. For example, an excimer laser (100 nm to 500 nm wavelength) may be used to ablate a substrate of silicon or copper. A chosen wavelength corresponds in part to a laser fluence energy of the material from which the substrate is formed. For example, a 355 nm wavelength with an internal power of approximately 45-48 micro-Joules might be used to form micro-channels in silicon.

Laser spot size, laser repetition rate, spot pitch, and spot overlap may be varied to achieve a desired material removal rate and surface roughness. For example, an 8 micron laser spot with a 33 kHz repetition rate, a raster speed of 16 cm/sec and a 55% spot overlap might be used to create channels of 100 micron width and 200-300 microns deep at 50, 75, or 90 micron pitch. Desired geometries may be obtained by varying the above described parameters.

As mentioned in regard to block 1006, micro-channel depth may vary corresponding to a heat flux to be incident to the heat exchanger base. For example, a plan-wise variable heat flux distribution may be incorporated into the laser milling control algorithm to effectuate deeper micro-channels in regions of high heat flux (see, e.g., FIG. 3) and shallower micro-channels in regions of low relative heat flux. Further, multiple lasers may be used to increase manufacturing throughput. Micro-channel fabrication may occur while the IC die remain integrated on the wafer, after die singulation, during package assembly, or before or after the substrate forming the fins and base is attached to an IC package.

### Method for Use for Non-uniform Depth Microchannels

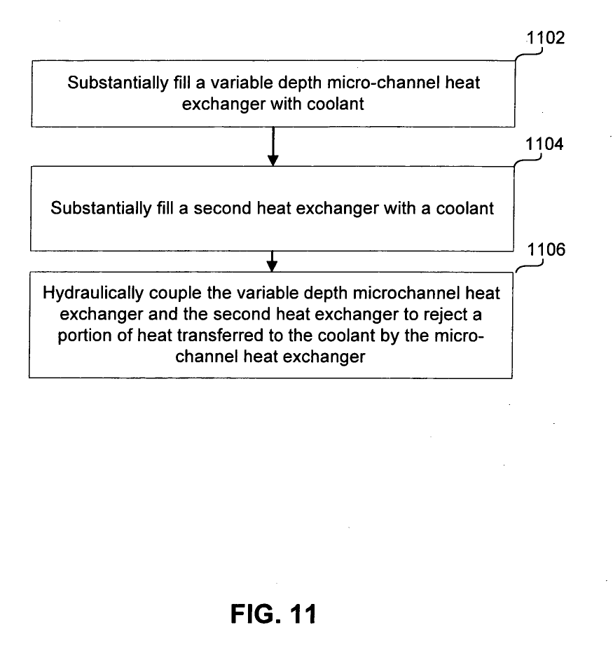

FIG. 11 illustrates a flowchart of a method for using a micro-channel heat exchanger. At block 1102, a variable depth micro-channel heat exchanger is substantially filled with coolant. At block 1104, a second heat exchanger to be used as a heat rejecter is substantially filled with coolant. At block 1106, the variable depth micro-channel heat exchanger and the second heat exchanger are hydraulically coupled such that the heat rejecter will reject a portion of heat transferred to the coolant by the variable depth micro-channel heat exchanger.

Although specific embodiments have been illustrated and described herein for purposes of description of the preferred embodiment, it will be appreciated by those of ordinary skill in the art that a wide variety of alternate and/or equivalent implementations calculated to achieve the same purposes may be substituted for the specific embodiments shown and described without departing from the intended scope of the present disclosure and claims. Those with skill in the art will readily appreciate that the present disclosure and claims may be implemented in a very wide variety of embodiments. This patent application is intended to cover any adaptations or variations of the embodiments discussed herein. Therefore, it is manifestly intended that this invention be limited only by the claims and the equivalents thereof.

What is claimed is:

1. A micro-channel heat exchanger comprising:
a base;
a first region of fins of first depth extending from one side of, and integral to, the base;
a second region of fins of second depth different from the first depth from the one side of, and intregal to, the base, wherein distal ends of the fins from the first region and the second region extend to the same height from the base;
a lid sealingly engaged to the distal ends of the fins.

2. The micro-channel heat exchanger of claim 1, further comprising a coolant that substantially consists of a selected one of the group consisting of water, propylene glycol, perflourinated fluid, an inorganic liquid, and a combination thereof.

3. The micro-channel heat exchanger of claim 1, wherein the base and plurality of fins are each formed integrally to a die substrate on which is disposed an integrated circuit.

4. The micro-channel heat exchanger of claim 1, wherein the base and plurality of fins are each formed integrally to a substrate to be thermally coupled to an integrated circuit package.

5. The micro-channel heat exchanger of claim 1, wherein a plan-wise variable rate of cooling corresponds, in part, to a plan-wise variable heat flux to be incident to the base.

6. The micro-channel heat exchanger of claim 1 further comprising the fins integral to the base to be formed by material removal that results from a laser milling process.

7. An integrated circuit cooling system comprising:
a coolant;
a channel heat exchanger with a base and a plurality of channels filled by the coolant and, and thereby, hydraulically coupled, the channel heat exchanger to thermally couple to an integrated circuit, wherein a depth of the channels of the channel heat exchanger varies in a plan-wise distribution to give a first region of channels a first depth and a second region of channels a second depth to provide a plan-wise variable rate of cooling;
a second heat exchanger to reject heat transferred to the coolant through the channel heat exchanger.

8. The integrated circuit cooling system of claim 7, wherein the coolant substantially consists of a selected one of the group consisting of water, propylene glycol, perflourinated fluid, an inorganic liquid, and a combination thereof.

9. The integrated circuit cooling system of claim 7, wherein the base and a plurality of fins that, in part, form the channels, are each formed integrally to a die substrate on which is disposed an integrated circuit.

10. The integrated circuit cooling system of claim 7, wherein the base and a plurality of fins that, in part, form the channels, are each formed integrally to a substrate to be attached to an integrated circuit package.

11. The integrated circuit cooling system of claim 7, wherein the plan-wise variable rate of cooling corresponds, in part, to a plan-wise variable heat flux to be incident to the channel heat exchanger.

12. The integrated circuit cooling system of claim 7, further comprising a plurality of fins integral to the base and formed by material removal that results from a laser milling process.

13. The integrated circuit cooling system of claim 7, wherein the channel heat exchanger, in conjunction with an incident heat flux, to vaporize a portion of the coolant, and the second heat exchanger to condense a portion of the coolant from a gas phase.

14. A method of manufacture for a variable depth micro-channel heat exchanger comprising:
ablating portions of a substrate to form a first region of fins protruding from and integral to a base;
ablating portions of a substrate to form a second region of fins protruding from and integral to the base, wherein a depth into the base of the first region and a depth into the base of the second region differs.

15. The method of claim 14 wherein a difference between the depth of the first region and the depth of the second region depends in part on plan-wise variation of heat flux to be incident to the base.

16. The method of claim 15, wherein an integrated circuit generates the plan-wise variation in heat flux and the integrated circuit comprises a selected one of the group including a microprocessor, a multiple core microprocessor, a graphics processor, a memory controller, an ASIC, and a chipset, or a combination thereof.

17. The method of claim 14, wherein the substrate is a semi-conductor on which an integrated circuit is disposed.

18. The method of claim 14, further comprising the substrate to attach to a semiconductor package that includes an integrated circuit.

19. The method of claim 14, wherein the substrate forms a portion of a selected one of the group consisting of a wafer prior to singulation, an integrated circuit die prior to incorporation into an integrated circuit package, and an integrated circuit die after partial assembly into an integrated circuit package.

20. A method of using a cooling system including a variable depth channel heat exchanger comprising:
substantially filling a channel heat exchanger with a coolant, wherein the channel heat exchanger includes a base and a plurality of channels, wherein a channel depth of the channel heat exchanger varies in a plan-wise distribution to give a first region of channels a first depth and a second region of channels a second depth, wherein fins that form the first region of channels and fins that form the second region of channels extend from one side of the base, and wherein substantially filling the channel heat exchanger with a coolant hydraulically couples the channels to provide a plan-wise variable rate of cooling;
substantially filling a second heat exchanger with the coolant; and
hydraulically coupling the micro-channel heat exchanger to the second heat exchanger to reject heat transferred to the coolant by channel heat exchanger.
